(19) United States
(12) Patent Application Publication
(10) Pub. No.: US 2025/0287483 A1
(43) Pub. Date: Sep. 11, 2025

(54) PROCESS OF OPERATING A P-N JUNCTION

(71) Applicants: Lin TIAN, Waterloo (CA); NORTHERN QUANTUM LIGHTS INC., Kitchener (CA)

(72) Inventors: Lin TIAN, Waterloo (CA); François SFIGAKIS, Waterloo (CA); Jonathan BAUGH, Waterloo (CA); Michael REIMER, Waterloo (CA); Zbig WASILEWSKI, Waterloo (CA)

(21) Appl. No.: 18/676,565

(22) Filed: May 29, 2024

Related U.S. Application Data
(60) Provisional application No. 63/504,772, filed on May 29, 2023.

(51) Int. Cl. H05B 45/00; H10H 20/00; H10H 20/824

(52) U.S. Cl. CPC H05B 45/00; H10H 20/062; H10H 20/824

(57) ABSTRACT

The process can include generating a first one of an electron gas and a hole gas at the first side of the p-n junction, and generating a second one of the electron gas and the hole gas at the second side of the p-n junction; discontinuing both the electron gas and the hole gas; generating the first one of the electron gas and the hole gas at the second side of the p-n junction; and discontinuing the first one of the electron gas and the hole gas at the second side of the p-n junction.

### BACKGROUND

P-n junctions such as dopant-free lateral p-n junctions in the GaAs/AlGaAs material system have received increased attention in recent years. In the case of dopant-free lateral p-n junctions in the GaAs/AlGaAs material system, significant interest is associated to their potential use in quantum optoelectronics (e.g., optical quantum computers or quantum repeaters) and ease of integration with other components, such as single electron pumps and spin qubits. A major obstacle to integration has been unwanted charge accumulation at the p-n junction gap that suppresses light emission, either due to enhanced non-radiative recombination or inhibition of p-n current. Typically, samples must frequently be warmed from cryogenic temperatures (e.g. lower than 100° K) back to room temperature to dissipate this built-up charge and restore light emission in a subsequent cooldown, which is undesirable. There always remains room for improvement.

### SUMMARY

It was found that a process of controlling gate voltage could allow to clear parasitic charge accumulation in-situ at low temperature, enabling cryogenic operation of devices over longer, potentially indefinite, periods. Such a process can enable the optical characterization of stable, bright, dopant-free lateral p-n junctions with electroluminescence linewidths among the narrowest (<1 meV) reported in this type of device for the ground state of neutral excitons. The binding and dissociation energies for free and charged excitons can be measured for in-plane electric fields ranging from 8 kV/cm to 80 kV/cm. An exciton lifetime of 237 ps was measured by time-resolved electroluminescence, and RF-pulsed operation at up to 1.6 GHz.

In accordance with one aspect, there is provided a process of operating a p-n junction having a first side and a second side, the first side being a first one of a p side and an n side, the second side being a second one of the p side and the n side, the process comprising: while maintaining the p-n junction at a temperature below 80° K, in sequence, 1) generating a first one of an electron gas and a hole gas at the first side of the p-n junction, and generating a second one of the electron gas and the hole gas at the second side of the p-n junction; 2) discontinuing both the electron gas and the hole gas; 3) generating the first one of the electron gas and the hole gas at the second side of the p-n junction; and 4) discontinuing the first one of the electron gas and the hole gas at the second side of the p-n junction.

All technical implementation details and advantages described with respect to a particular aspect of the present invention are self-evidently mutatis mutandis applicable for all other aspects of the present invention.

Many further features and combinations thereof concerning the present improvements will appear to those skilled in the art following a reading of the instant disclosure.

### DESCRIPTION OF THE FIGURES

In the figures,

FIG. 1 is a schematic view of an example system having a refrigerated semiconductor device which can have one or more p-n junction in a refrigerator;

FIG. 2 is a schematic view of an example semiconductor device;

FIG. 3 presents device structure, electroluminescence, and light emission decay at temperature T=3 K. Ambipolar operation and diode behavior. (a) Schematic diagram of a dopant-free lateral p-n junction device, including the epitaxial layers of the quantum well (QW) heterostructure. (b) Composite photograph of a dopant-free lateral p-n junction, as well as the electrical circuit used in all low-frequency measurements. Note both sides of the p-n junction have ambipolar ohmic contacts, allowing a two-dimensional electron gas (2DEG) or a two-dimensional hole gas (2DHG) to form on either side. V_{tgL} is the topgate voltage on the left side, and V_{tgR} is the topgate voltage on the right. Vₚₙ is the forward bias, used to drive current across the p-n junction. Band structure diagram across the p-n junction in the quantum well plane, when the device is operated in: (c) PN mode and (d) NP mode; closed blue circles represent electrons in a 2DEG, and open red circles represent holes in a 2DHG. Diode current when sample C is operated in: (e) PN mode with V_{tgL}=−5 V and V_{tgR}=+5 V, and (f) NP mode with V_{tgL}=+5 V and V_{tgR}=−5 V. (g) Wide-energy spectrum of EL emission from sample C at T=3 K (raw emission output: no optical filters present in setup), with |V_{tgL}|=|V_{tgR}|=5 V, and Vₚₙ=1.6 V. (h) EL intensity in sample E with V_{tgL}=−5 V, V_{tgR}=+5 V, and T=1.6 K, in DC mode (without a set-reset top-gate voltage sequence, see main text). Light emission decays faster at higher Von. Solid lines are guides to the eye.

FIG. 4 presents benefits of lateral p-n junction operating continuously in the Set-Reset mode. (a) (inset) Diagram of the Set-Reset voltage sequence for topgates with time, while Vₚₙ is held constant. If Vₚₙ>+1.5 V, then the diode switches between ON/OFF states, as indicated by the highlighted labels. The periodicity of the Set-Reset sequence is determined by the Set-Reset frequency fₛᵣ. (a) (main) Integrated electroluminescence of sample E acquired in DC mode (green triangles) and in Set-Reset mode (red crosses), with |V_{tgL}|=|V_{tgR}|=5 V at T=1.6 K. EL does not decay in the Set-Reset mode, unlike the DC mode. The EL intensity in Set-Reset mode was normalized to the maximum intensity in DC mode. (b) Integrated EL intensity (red circles) as a function of fₛᵣ, in sample B with |V_{tgL}|=|V_{tgR}|=5 V, Vₚₙ=1.55 V, and at T=3 K. The dashed line is a fit to Eqn. (2).

FIG. 5 presents characteristics of lateral p-n junction operating continuously in the Set-Reset mode. (a) EL intensity as a function of forward bias Vₚₙ in sample C, with fₛᵣ=10 Hz, T=3 K, and |V_{tgL}|=|V_{tgR}|=5 V. (b) Comparison of EL spectra in PN mode and NP mode in sample C, with fₛᵣ=10 Hz, |V_{tgL}|=|V_{tgR}|=5 V, and Vₚₙ=1.55 V. Comparison between PL and EL spectra (fₛᵣ=10 Hz) from the same 15 nm wide GaAs quantum well (G375). The EL is from sample B, with fₛᵣ=10 Hz, |V_{tgL}|=|V_{tgR}|=5 V, and Vₚₙ=1.55 V. (c) X⁰ and LH peaks at T=85 K with fₛᵣ=1 kHz in sample A. The LH peak only becomes evident at high temperatures T>30 K. Both X⁰ and LH have redshifted in energy, almost entirely due to the temperature dependence of the GaAs bandgap.

FIG. 6 presents time-resolved EL from sample E in Set-Reset mode with fₛᵣ=10 Hz and |V_{tgL}|=|V_{tgR}|=5 V. (a) Periodic RF-pulsed EL at T=1.6 K with Vₚₙ=1.47 V (dc)+0.5 Vₚ₋ₚ (rf). The RF pulse was a square wave with repeat frequency 100 MHz (10 ns period) with a nominal 10% duty cycle. (b) Analysis of a single RF-driven EL light pulse. From fitting the experimental data (blue circles) to an exponentially modified Gaussian (EMG; dashed red line), an EL exciton lifetime τ el=237 ps is obtained. (inset) By comparison, the PL exciton lifetime from the same quantum well heterostructure is almost twice longer, τ pl=419 ps.

FIG. 7 is a schematic of an example computer.

### DETAILED DESCRIPTION

High-mobility two-dimensional electron/hole gases (2DEG/2DHG) in semiconductor heterostructures have yielded decades of advancement in quantum electronic transport, but have yet to make a significant impact in the field of optoelectronics. Lateral p-n junctions (2D planar light-emitting transistors) have been achieved in undoped GaAs/AlGaAs heterostructures allowing future integration with single-electron devices for photonic applications. A significant goal of quantum optoelectronics is the realization of an all-electrical, deterministic source of quantum states of light. By combining a source of single electrons (e.g., a non-adiabatic single electron pump) with a lateral p-n junction, the on-demand generation of single or entangled photons is possible. Such sources would have immediate relevance for practical quantum sensing, communication and cryptography, and could benefit from the inherent scalability of lateral semiconductor devices (e.g., for multiplexing). If such sources were integrated with spin qubits, spin-to-photon conversion schemes could improve the scalability prospects for solid-state quantum computers. Another desirable application in quantum optoelectronics is photon-to-spin conversion, a necessary component of spin-based quantum repeaters for long-distance quantum communication.

Studies on lateral p-n junctions involved modulation-doped heterostructures and various selective etching techniques. Early successes included observing the spin Hall effect through spin-to-photon conversion and demonstrating anti-bunching in the few-photon regime. However, the presence of dopant impurities and an etched surface at the p-n junction itself can cause non-radiative recombination (reducing efficiency) and parasitic radiative recombination at different wavelengths.

It was found that limitations identified above could be circumvented in the case of a dopant-free GaAs/AlGaAs heterostructure-insulator-gate field effect transistor (HIGFET) geometry. This type of device architecture (n-type or p-type) is normally switched off unless a gate voltage beyond a turn-on threshold is applied, inducing a two dimensional electron gas (2DEG) or a two dimensional hole gas (2DHG) underneath the gate depending on whether the voltage is positive or negative. Furthermore, relative to their conventional modulation-doped counterparts, dopant-free devices have exceptional reproducibility and low disorder.

Dopant-free p-n junctions have already been demonstrated, which generally show narrower electroluminescence (EL) emission peak linewidths than their modulation-doped counter-parts. A dopant-free single-photon source incorporating a dopant free p-n junction, driven by surface acoustic waves, was also realized. However, the brightness of dopant-free p-n junctions can decay with time, requiring thermal cycling from cryogenic to room temperature to restore (reset) the electrical properties and brightness of the device.

It was found that the brightness decay in p-n junctions, such as p-n junctions using dopant-free GaAs/AlGaAs quantum wells, can be overcome by implementing a sequence of gate voltages in-situ at low temperature to completely restore the device, in a manner which may avoid the need for thermal cycling. It was also found that narrower EL linewidths may be observed in lateral p-n junctions, whether doped or undoped. Well-defined EL emission peaks may be visible up to a temperature of T=85 K, which we unambiguously identify as the ground state of neutral free excitons (one peak each for heavy and light hole excitons) and the ground state of a heavy hole trion. Using many samples, the binding and dissociation energies of free excitons and trions can be measured as a function of in-plane electric fields ranging from 8 kV/cm to 80 kV/cm. Using pulsed-EL, can achieve an exciton lifetime of 237 ps, and RF operation of devices at frequencies up to 1.6 GHZ, may be achieved, depending on the limits of the RF equipment used. The implemented gate voltage sequence, which we call the Set-Reset sequence, is a significant step towards realizing viable quantum light sources based on dopant-free 2DEGs and 2DHGs. Since the process of resetting the p-n junction can find uses in the case of dopant free lateral p-n junctions based on dopant-free GaAs/AlGaAs heterostructure-insulator-gate field effect transistor geometry, it will be understood by persons having ordinary skill in the art that the process may find uses in semiconductor devices having other geometries or types p-n junctions.

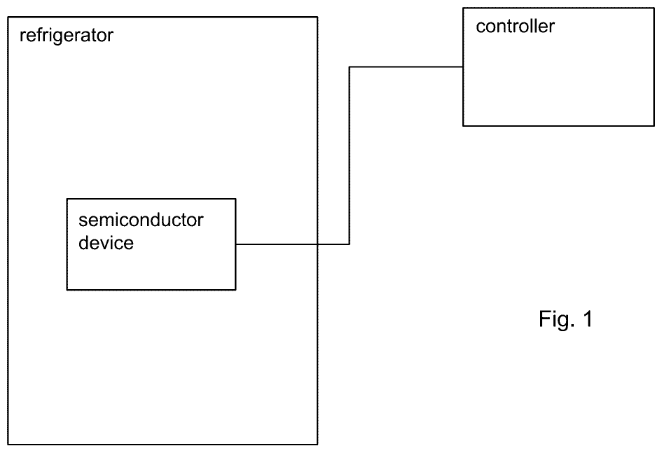

To begin describing the set-reset process, let us first turn to FIG. 1 which presents a schematic illustration of a semiconductor device which may have a p-n junction. The semiconductor device can be maintained at a temperature below 80K, or below 100K, or even lower, during the set-reset process by introducing it in a refrigerated cavity of a refrigerator. The refrigerator can be a dilution refrigerator for instance. The semiconductor device operation typically involves the application of different voltages at different contacts or gates. The application of the different voltages it typically controlled by a system which will be referred to herein as a controller, and which typically embodied as a computer. The controller can be outside the refrigerator, and connected to the different contacts or gates via wires or cables which go across a wall of the refrigerator.

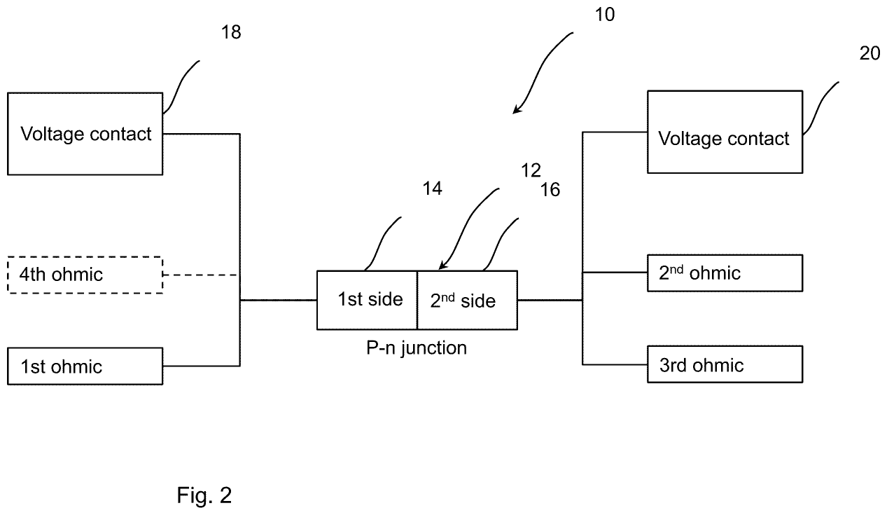

Turning now to FIG. 2, an example of semiconductor device 10 having a p-n junction 12 is presented. The p-n junction 12 is integrated into the semiconductor device 10 which also includes a number of different contacts or gates, and an electrical circuit connecting the different contacts or gates to the p-n junction 12. The p-n junction 12 can have a first side 14 and a second side 16. The first side 14 can be a first one of a p-side and an n-side, with the second side 16 being the other one of the p-side and the n-side, depending of whether the junction is a p-type of n-type p-n junction. The p-n junction 12 is a heterostructure of semiconducting materials and exhibits a band gap. In a relatively simple expression, the p-n junction 12 has a first ohmic, such as p-ohmic or a n-ohmic. Applying a first voltage at a first voltage contact 18, above a turn-on voltage threshold, may generate a first one of an electron gas and a hole gas (depending on whether the voltage is positive or negative, and of the nature of the first contact) at the first side 14 of the p-n junction 12. The p-n junction has another contact 20 which will be referred to as the second voltage contact for convenience, via which a second voltage may be applied simultaneously to the first voltage, above a corresponding turn-on voltage threshold, in a manner to generate the second one of the electron gas and the hole gas at the second side of the p-n junction, e.g. at a corresponding one of a p-ohmic or n-ohmic associated to the second side. This step can be referred to as “setting”. At one point, parasitic particles (electrons or holes) may tend to accumulate in an undesired manner at one or more location of the semiconductor device 10 and affect the operation of the semiconductor device 10. The first step can be discontinued. In other words, at a second step, the voltages at the first and second contacts 18, 20 can be controlled in a manner to interrupt the electron gas and the hole gas which was generated at the first step. This can involve changing the voltages at the first and second contact 18, 20 to below a turn-off threshold. Then, in a third step, the first one of the electron gas and the hole gas can be applied at the second side of the p-n junction 12. This can involve applying a third voltage at the second voltage contact 20, for instance, above a corresponding turn-on voltage threshold (which may be negative instead of positive here, or vice-versa), effecting a reversal which can be referred to herein as “resetting”. In other words, if an electron gas was generated at the first side during the first “setting” step, an electron gas can be generated at the second side during the “resetting” step. In this third step, trapped particles (electrons or holes) can be returned to their intended location in the semiconductor device. In one mode of operation, the first side of the p-n junction 12 can be maintained at a set voltage during the “resetting step”. In another mode of operation, which may have advantages such as more efficient or quicker evacuation of stray charges in some embodiments, the second one of the electron gas and the hole gas can be generated at the first side during the third step. In other words, if a hole gas was generated at the second side during the first step, a hole gas can be generated at the first side during the third step whereas if an electron gas was generated at the second side during the first step, an electron gas can be generated at the first side during the third step. In the example presented in FIG. 2, this can be achieved via an optional additional ohmic referred to as a fourth ohmic. Then, in a fourth step, the gas(ses) generated at the third step can be discontinued, which can involve bringing the voltage at the corresponding contact(s) below the corresponding turn-off threshold.

The steps referred to above can be performed while the semiconductor device 10 is maintained at cryogenic temperatures, such as below 80K, below 100K, or even lower. Moreover, it was found that in some embodiments, it could be more effective to repeat the four steps of the process described above to “reset” the device without having to bring the device back to room temperature, such as repeating the process more than 10 times, more than 50 times, or even more. In yet other embodiments, it could be even more effective to repeat the process at a certain frequency, such as above 1 Hz, above 10 Hz, above 1 kHz, or at even higher frequencies.

In some embodiments, it can be desired to apply a voltage difference across the p-n junction 12 to perform an operation. For instance, a voltage difference can be applied across the p-n junction, above a band gap of the p-n junction, to generate light at the p-n junction. Such voltage can be applied via other contacts. The applied voltage can be referred to as a forward bias or a reverse bias depending on the particularities of the operation of the p-n junction. In such embodiments, the application of the bias may lead, after a certain amount of time which may be relatively short or relatively long, to accumulation of charges at undesired locations in the semiconductor device 12, which may affect the desired operation of the semiconductor device 12 under the bias. In one mode of operation, the bias may be discontinued prior to performing the resetting process described above. In another mode of operation, the resetting process described above may be performed while applying the bias. For instance, in one embodiment, the four steps can be repeated at a certain frequency while applying a bias leading to the emission of light at the p-n junction.

### Example Results and Analysis

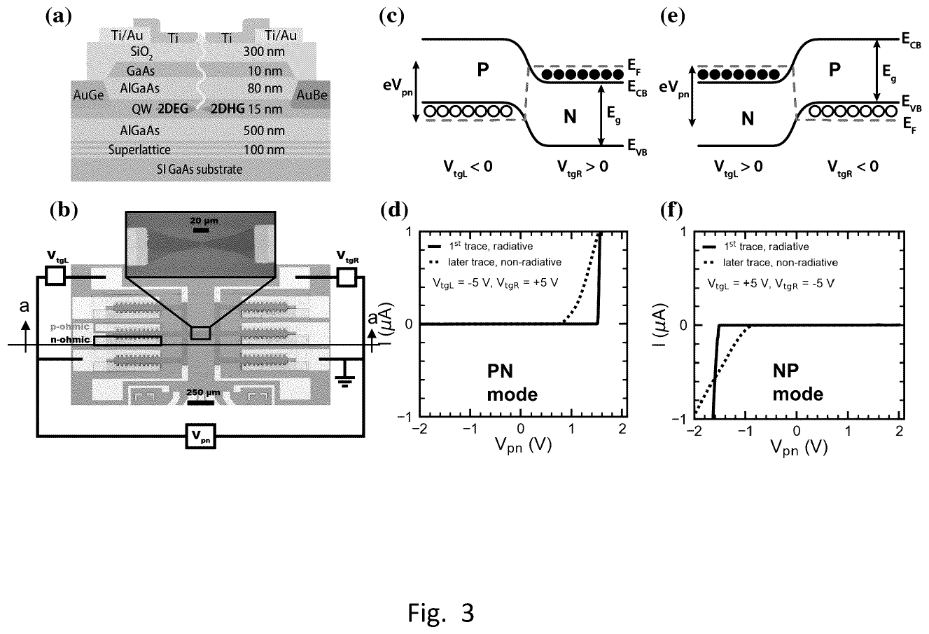

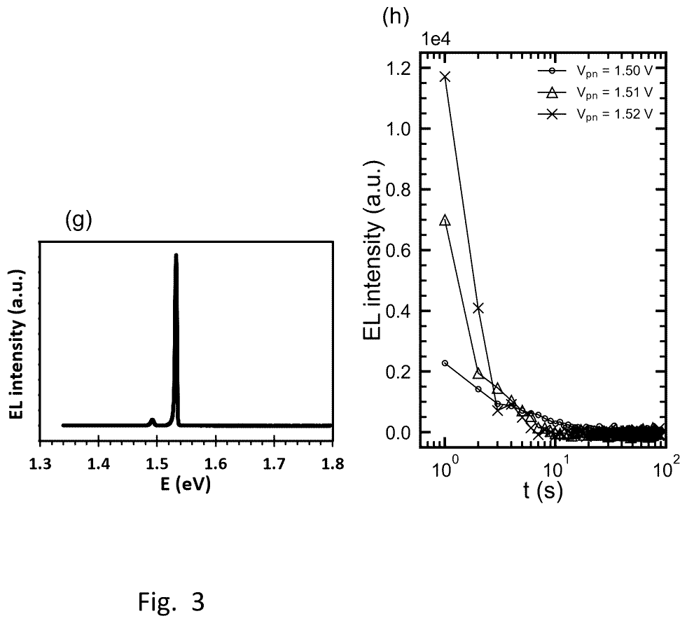

Experiments were made with five dopant-free lateral p-n junctions (samples A, B, C, D, and E—see table 1 below), with a p-n junction gap monotonically increasing from 200 nm (sample A) to 2000 nm (sample E). Samples A-D were fabricated on wafer G375, and sample E was fabricated on wafer G569. FIG. 3(a) shows the vertical cross-section of all layers (growth and fabrication) of these devices. A schematic of the electrical circuit and an optical photograph of a completed dopant-free ambipolar lateral p-n junction are depicted in FIG. 3(b).

Due to their ambipolar functionality, devices can be operated either in the PN mode see FIG. 3c or in the NP mode (FIG. 3d).

More specifically, FIG. 3c shows the bandstructure of a dopant-free lateral p-n junction operated in PN mode, defined as when V_{tgL}<0 and V_{tgR}>0, whereas FIG. 1d shows the bandstructure of the same device operated in NP mode, when V_{tgL}>0 and V_{tgR}<0. FIG. 3e demonstrates the measured diode behavior when the lateral p-n junction is operated in PN mode (red solid trace). Current only flows when Vₚₙ>+1.5 V in forward bias, and no current flows in reverse bias (i.e., Vₚₙ<0). The diode turn-on threshold is at the expected value for the GaAs bandgap (˜1.5 eV). The ambipolar device behaves identically when operated in the NP mode (see FIG. 3f). However, all samples showed strong hysteretic behavior after the first Vₚₙ sweep: each subsequent sweep had a different turn-on Vₚₙ bias and ideality factor. The blue dashed lines in FIGS. 3e,f are examples of such non-reproducible sweeps. Most importantly, radiative electron-hole recombination only occurred during the first Vₚₙ sweep. Subsequent Vₚₙ sweeps usually did not produce any light emission, unless either Vₚₙ or V_{tg} (we use V_{tg} to refer to either/both V_{tgR} or V_{tgL}.) were increased beyond values used in previous sweeps. After a thermal cycle to room temperature and back down to cryogenic temperatures, device characteristics are fully restored: red trace lines in panels (c) and (d), with its associated light emission.

The turn-on threshold is at the expected value for the GaAs bandgap (˜1.5 eV), such that diode current only flows when Vₚₙ>+1.5 V in forward bias and no current flows in reverse bias (i.e., Vₚₙ<0), shown in FIGS. 3(e) and 3(f) of the supplementary material. FIG. 1(g) shows a typical electroluminescence spectrum.

When Vₚₙ, V_{tgL}, and V_{tgR} are kept constant (i.e., in DC mode), FIG. 3(h) illustrates the principal problem in an example dopant-free p-n junction: EL intensity (but not necessarily diode current) decays with time, to the point where it may vanish within seconds. Of note, with higher initial p-n currents, light emission is suppressed at a faster rate. The latter is indicative of charging effects, either enhancing non-radiative electron-hole recombination or suppressing current altogether. “Dark” samples can be reset with a full thermal cycle: warming up electrically grounded samples to room temperature for several hours. Initial device behavior, with its associated light emission, can be completely recovered. While effective, such thermal cycles are not practical for detailed optoelectronic characterization or applications.

As an alternative to a full thermal cycle, the Set-Reset voltage sequence applied to both V_{tgL} and V_{tgR} topgates can completely reset a dopant-free lateral p-n junction in-situ at low temperatures, such that the first-trace characteristics (including light emission) are fully recovered. The Set-Reset sequence involves alternating the polarities of V_{tgL} and V_{tgR}, while keeping Vₚₙ fixed (e.g., Vₚₙ=0). The periodicity of the voltage sequence is determined by the Set-Reset frequency fₛᵣ. This process may be more efficient when (i) the magnitude of the topgate voltages is large enough to alternately induce a 2DEG and 2DHG on each side of the p-n junction (i.e. above a turn-on voltage), and (ii) the voltage sequence has many cycles (50-500), where each cycle switches the topgate voltage polarities back and forth once. In effect, the device alternates between PN mode and NP mode. Alternating the polarity of Vₚₙ while holding V_{tgL} and V_{tgR} constant was not observed to reset a device.

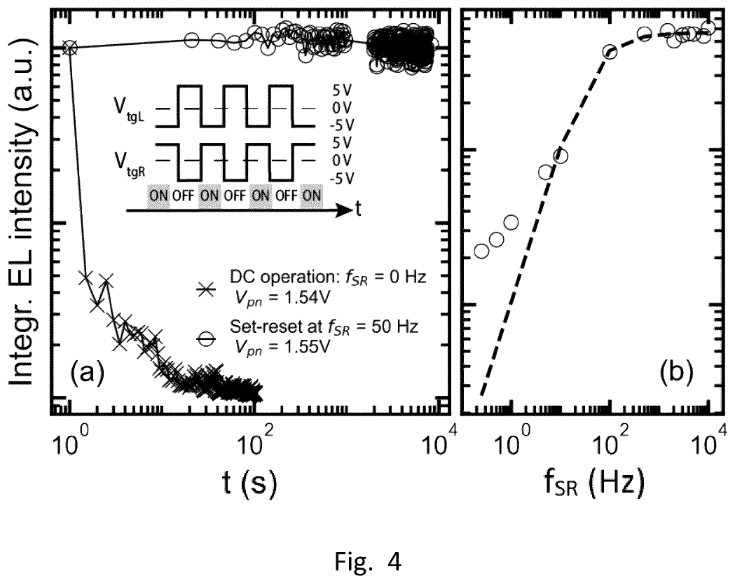

However, once reset, a device can still degrade again. Instead of applying the Set-Reset sequence before/after a set of measurements, one can continuously apply the Set-Reset voltage sequence with Vₚₙ>1.52 V (i.e. greater than the diode turn-on threshold), during optical data acquisition. In this configuration, the Set-Reset sequence modulates the on/off states of the p-n junction, by switching between forward bias (“set”) and reverse bias (“reset”) without changing Vₚₙ [see inset of FIG. 4(a)], in a set-reset mode.

The main panel of FIG. 4(a) illustrates the dramatic difference between operating a dopant-free p-n junction in DC mode and Set-Reset mode. In DC mode, EL emission disappears very rapidly (<10 seconds). In stark contrast, the Set-Reset mode yields an integrated EL intensity that does not decay over at least 104 seconds. In fact, it has been observed to remain bright for at least 48 hours, the longest period over which EL intensity was continuously tracked. Crucially, optical characteristics are reproducible for a given set of experimental parameters.

FIG. 2(b) shows the effects of fₛᵣ on the integrated EL intensity. As for increases from 0.25 Hz to 500 Hz, the EL emission becomes brighter. This makes sense for samples with time-decaying brightness: the average intensity during the light emission portion of a single set-reset cycle increases as the frequency becomes larger. Assuming emission intensity I el decays as I el (t)=I₀ e^{-t/τ}^{_{d}}, where I₀ is the initial EL intensity at time t=0 and τ_{d} is the EL decay's mean lifetime (or half-life τ_{d} ln 2), the integrated intensity is:

$${I}_{Σ} = \frac{Δ t}{T sr} {\int }_{0}^{T sr} I el ( t ) dt , \qquad ( 1 )$$

where Δt is the data acquisition integration time, T sr is the period of a single Set-Reset cycle (T sr=1/f sr), and the condition T sr<Δt is met. Performing the integral in Eqn. (1) on our ansatz for I(t) yields:

$${I}_{Σ} ( f s r ) = {I}_{0} Δ t {τ}_{d} f sr ( 1 - {e}^{- 1 / {τ}_{d} f sr} ) . \qquad ( 2 )$$

When τ_{d}f sr»1, Eqn. (2) predicts I_{Σ} will saturate. In other words, when the set-reset period is very short (T sr»τ_{d}), the EL emission does not significantly decay during a single set-reset cycle, and I_{Σ} becomes independent of f sr. When the set-reset period is very long (T sr»τ_{d}), the EL emission decays significantly during a single set-reset cycle, and Eqn. (2) predicts I_{Σ} grows linearly with f sr. The experimental data in FIG. 2(b) is broadly consistent with Eqn. (2) but, in the regime T sr>τ_{d}, the experimental I_{Σ} is not a simple linear function of f sr. Nevertheless, fitting Eqn. (2) to this experimental data yields τ_{d}≈0.2 seconds, which implies that the signal strength has already reduced by two orders of magnitude during the first second of data acquisition (from t=0 to t=1 s) when operating in DC mode.

TABLE 1
EL emission energies of X⁰ and X⁻ in all samples reported here. Also
listed are their gaps between the p-type and n-type regions (i.e., the
distance separating the V_{tgL} and V_{tgR} topgates in FIG. 1(a)), their X⁰
binding energies E_{bx}, their X⁻ dissociation energies ΔE_{X}_{^{−}} = Eₑₗ(X⁰) −
Eₑₗ(X⁻), and the full width at half maximum (FWHM) of their X⁰ peaks.
Samples A, B, C, and D come from wafer G375, and sample E comes
from wafer G569. Both wafers have a nominal 15 nm quantum well width.

| | Gap | Eₑₗ(X⁰) | Eₑₗ(X⁻) | E_{bx} | ΔE_{X}_{^{−}} | fwhm |
|---|---|---|---|---|---|---|
| Sample | (m) | (meV) | (meV) | (meV) | (meV) | (meV) |
| A | 0.2 | 1534.1 | 1532.3 | 8.8 | 1.8 | 1.20 |
| B | 0.4 | 1534.3 | 1532.6 | 8.8 | 1.7 | 0.70 |
| C | 1.2 | 1534.4 | 1532.8 | 8.8 | 1.6 | 0.78 |
| D | 1.2 | 1534.4 | 1532.8 | 8.8 | 1.6 | 0.92 |
| E | 2.0 | 1534.7 | 1533.3 | 8.8 | 1.4 | 0.92 |

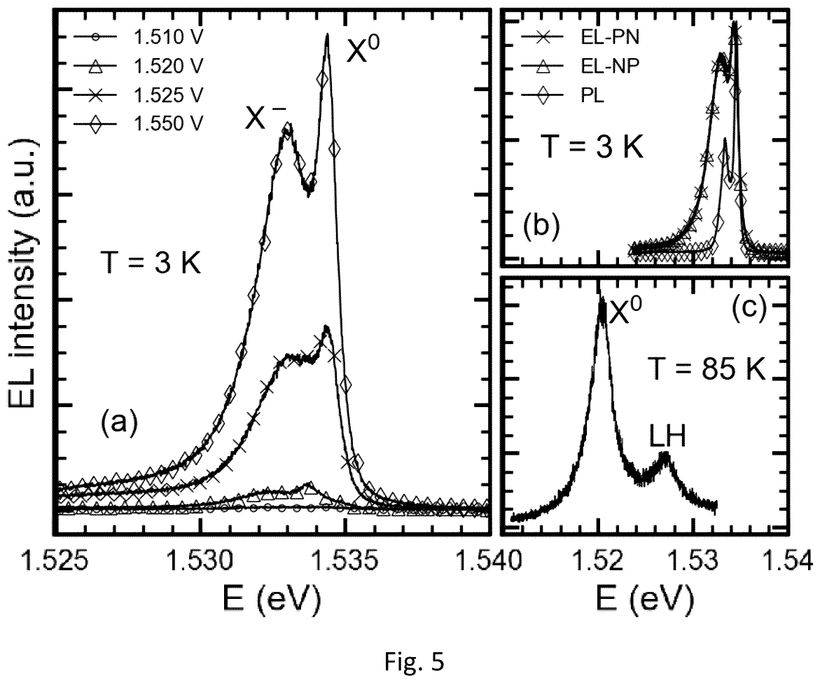

A series of experiments, described in FIG. 5, confirm that the Set-Reset mode may not introduce anomalous behavior. These experiments are summarized in the following three paragraphs. Without the Set-Reset protocol, some of these experiments would have been challenging to carry out.

FIG. 5(a) shows EL spectra at different Vₚₙ, with light emission occurring only once the forward bias exceeds the bandgap of bulk GaAs (Vₚₙ>1.519 eV). We attribute the narrowest peak (E˜1.534 eV) to the neutral exciton X⁰ ground state for a 15 nm wide GaAs quantum well, and the lower-energy peak (E˜1.533 eV) to a negatively-charged exciton (trion) X⁻.

FIG. 5(b) shows EL spectra from the same p-n junction in the PN and NP mode configurations. Indeed, because of the continuous Set-Reset topgate voltage sequence, without physically changing any electrical connections, the “ON” state of the PN configuration corresponds to Vₚₙ=+1.55 V, V_{tgL}<0, and V_{tgR}>0, whereas the “ON” state of the NP configuration corresponds to Vₚₙ=−1.55 V, V_{tgL}>0, and V_{tgR}<0. Not all samples emit in PN and NP modes with equal EL intensities. FIG. 5(b) also compares non-resonant photoluminescence (PL) to electroluminescence (EL) spectra from the same wafer. The emission energies for X⁰ match very well, with Eₑₗ=1,534.4 meV and Eₚₗ=1,534.6 meV (same Eₚₗ for both wafers G375 and G569). Furthermore, the EL and PL X⁰ emission energies are consistent with the trend of published values for PL X⁰ in GaAs quantum well widths ranging from 6 nm to 30 nm.

The FWHM of the PL X⁰ peak is 0.51. It is smaller than any of the FWHM for EL X⁰ listed in Table 1, because EL occurs at much higher carrier densities (causing more electron-exciton scattering), higher electric fields (from both Vₚₙ and V_{tg}), and possibly higher temperatures (due to Joule heating from the p-n current).

The disappearance of X⁻ as the temperature increases from 3 K to 30 K unambiguously confirms its identity as a trion. As the temperature is further increased from 30 K to 85 K, a new peak emerges, labeled “LH”, and grows in relative strength to X⁰ with increasing temperature (not shown). FIG. 5(c) shows X⁰ and LH at T=85 K.

Table 1 lists the emission energies and full width at half maximum (FWHM) of X⁰ in all samples reported here, obtained by fitting the EL lineshape. The physical origin of the long-tail on the low-energy side of the X-peak is most likely inelastic trion-electron scattering, considering the trions form in an electron-rich environment.

Four of the five samples listed in Table 1 have narrower linewidths (0.7-0.9 meV) than the narrowest linewidths (1.0-1.6 meV) of any lateral p-n junctions reported in the literature, whether undoped or modulation-doped.

The most likely reason for such narrow linewidths is the high quality MBE growth, as evidenced by the clean PL spectrum and the high electron/hole mobilities. However, we speculate that, in the vicinity of the p-n junction, the Set-Reset voltage sequence clears away parasitic charge that causes additional scattering, and hence reduces the broadening of EL emission.

As the p-n junction gap between the V_{tgL} and V_{tgR} topgates decreases from 2000 nm to 200 nm, both X⁻ and X⁰ show a very weak Stark shift (0.6 meV) to lower EL energies in Table 1 due to the increasing in-plane electric field |\vec{E}ₑₓₜ|=Vₚₙ/gap, ranging from 7.8 kV/cm (in sample E) to 78 kV/cm (in sample A) in the 2DEG/2DHG plane. With out-of-plane electric fields (of order 10 kV/cm), a large decrease (of order ˜20 meV) in Eₚₗ has been reported with photoluminescence. However, with in-plane electric fields, the only effects reported are an absence of any energy shift in Eₚₗ and a rapid broadening of PL peaks, leading to the near-complete smearing of all PL peaks by 16 kV/cm. Unlike past PL experiments with in-plane electric fields, we do not observe EL linewidths to rapidly increase with increasing in-plane electric fields, and all our EL linewidths are much narrower than the reported PL linewidths (0.7-0.9 meV versus 4.7-5.0 meV at their narrowest). Our narrow EL linewidths in turn allowed the observation of the small but noticeable shift in Eₑₗ; this small shift would likely have been masked by the rapid and large linewidth broadening reported in the original PL experiments. Indeed, the decrease in Eₑₗ(X⁰, X⁻) is not due to Joule heating (which would cause the bandgap to decrease): sample A, which has the smallest p-n junction gap and hence the smallest electrical resistance across the gap (i.e. the smallest heat dissipation), has the largest decrease in Eₑₗ, whereas the converse is true for sample E (i.e. the largest p-n junction gap but the smallest decrease in Eₑₗ).

A possible reason for the near-absence of broadening is that Vₚₙ=1.55 V was kept constant for all our samples, such that the in-plane electric field was only changed by the size of the gap between the V_{tgL} and V_{tgR} topgates. This limited the amount of voltage broadening in EL spectra. By contrast, to achieve an in-plane electric field of 16 kV/cm, a source-drain bias of 40 V (with a 2.7 A current) was applied across the 25 m gap (with 15 M resistance) between two ohmic contacts. Such a large bias window (26 times larger than Vₚₙ=1.55 V) would have caused significant voltage broadening to PL spectra in the original experiment. Indeed, the concept of voltage broadening did not gain wide acceptance among experimentalists until the late 1990s, now colloquially known as “electron temperature” (the combination of thermal and voltage broadening) when 2DEGs are involved.

The emission energy of EL X⁰ can be decomposed into the following contributions:

$${E}_{el} ( {X}^{0} ) = {E}_{g} - \vec{p} \cdot {\vec{E}}_{ext} + {E}_{e - q w} + {E}_{h - q w} - {E}_{b x} \qquad ( 3 )$$

where E_{g} is the GaAs bandgap energy, \vec{p} is the free exciton dipole moment, \vec{E}ₑₓₜ is the in-plane electric field, E_{e-qw} (E_{h-qw}) is the lowest-energy bound state in the quantum well conduction (valence) band CB (VB), and E_{bx} is the binding energy of the neutral exciton. Taking into account the small redshift \vec{p}·\vec{E}ₑₓₜ due to the Franz-Keldysh effect, the spatial asymmetry in the effective mass of heavy holes, the bandgaps of GaAs and Al_{0.3}Ga_{0.7}As and their band offsets, and the energy of the ground state for holes and electrons in the GaAs quantum well, the binding energy of EL X⁰ is calculated to be E_{bx}=(8.8±0.2) meV (see Table 1) for wafer G375, consistent with reported PL experiments and theory. Indeed, we use the isotropic mass mₑ*=0.067 m₀ for electrons in our 15 nm wide quantum well, where m₀ is the electron rest mass 9.11×10⁻³¹ kg. Heavy holes have different masses in different crystal directions. We use an average effective hole mass, the optical mass mₕₕ=(m_{z}*m_{y}*mₓ*)^{1/3}, where m_{z}*=0.377 m₀ in the crystal direction (MBE growth direction) and m_{y}*=mₓ*=0.112 m₀ in the and crystal directions.

Unexpectedly, the trion dissociation energy appears to increase with higher in-plane electric field (see Table 1). There is no ambiguity as to whether ΔE_{X}_{^{−}} is increasing or not with in-plane electric field, since it is directly obtained from the difference in emission energies ΔE_{X}_{^{−}}=Eₑₗ(X⁰)−Eₑₗ(X⁻). The emission energy of EL X⁻ can be decomposed into the following contributions:

$${E}_{e l} ( {X}^{-} ) = {E}_{g} - \vec{p} \cdot {\vec{E}}_{e x t} + {E}_{e - q w} + {E}_{h - q w} - {E}_{b x} - Δ {E}_{{x}^{-}} . \qquad ( 4 )$$

An increase in the dissociation energy of trions with larger in-plane electric field has been experimentally observed and theoretically justified in InGaAs/GaAs quantum dots, in the presence of strong spin-orbit coupling.

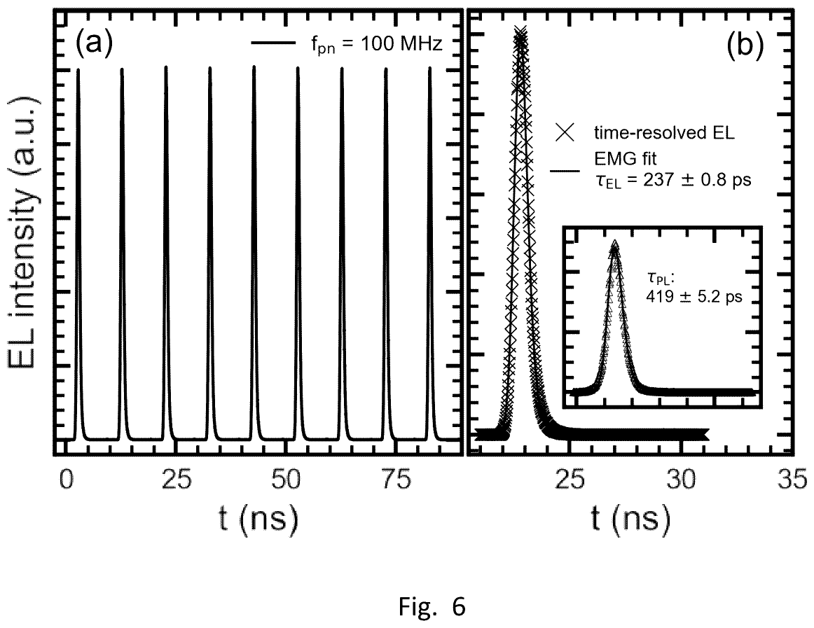

FIG. 6 demonstrates that the Set-Reset mode is compatible with radio frequency (RF) operation of lateral p-n junctions. The electrical circuit used is shown in Figure S9 from the supplemental material. The lineshape of the EL peaks in FIG. 4 is dictated in part by the limitations of the RF equipment (max. rise time of 0.95 ns/0.6 Vₚ₋ₚ); the attenuated RF pulses reaching the samples are very unlikely to be square-shaped pulses. Nevertheless, the lateral p-n junction is clearly responsive on timescales of less than 1 ns [see FIG. 6(a)]. Analysis of time-resolved luminescence in FIG. 6(b) reveals an exciton lifetime of τ el=237 ps for EL and τ pl=422 ps for PL. The shorter lifetime of EL relative to PL is consistent with the wider FWHM observed in EL relative to PL [see FIG. 5(b)]. In another RF experiment, using a sine wave from an RF generator Stanford Research Systems model SG392, EL was detected up to a frequency of 1.6 GHZ (not shown), despite the fact that the devices themselves were not optimized for RF operation (e.g., impedance-matched on-chip coplanar waveguides, minimum topgate area, etc.). This 1.6 GHz upper limit is due to RF transmission losses inside the cryostat rather than the maximum operating response from the p-n junction.

Hypothetically, in the single photon regime, an exciton lifetime τ el=237 ps would be compatible with a 1 GHz emission rate for a single photon source. Higher carrier densities, a narrower quantum well, or higher electric fields (from Vₚₙ) could reduce the EL lifetime further, possibly enabling a higher photon emission rate.

In the experiments presented above:

Concerning MBE growth, the following quantum well heterostructure (wafer G375) was grown by molecular beam epitaxy (MBE), starting from a semi-insulating (SI) GaAs (100) substrate [see FIG. 3(a)]: a 200 nm GaAs buffer, a 20-period smoothing superlattice (SL) composed of a 2.5 nm GaAs layer and 2.5 nm Al_{0.3}Ga_{0.7}As layer, a 500 nm Al_{0.3}Ga_{0.7}AS bottom barrier, a 15 nm wide GaAs quantum well, a 80 nm Al_{0.3}Ga_{0.7}As top barrier, and a 10 nm GaAs cap layer. There was no intentional doping anywhere in the heterostructure. Another quantum well wafer heterostructure (wafer G569) was also grown, which is nominally identical to G375 except for the 20-period smoothing superlattice buffer being replaced by a 500 nm LT-GaAs buffer followed by a 1,000 nm GaAs buffer. Wafer G375 (G569) was used to fabricate samples A-D (E).

Concerning sample fabrication, Hall bars and p-n junctions were fabricated, all oriented in the high mobility crystal direction [11̅0]. Briefly, after a mesa etch, Ni/AuGe/Ni n-type ohmic contacts and AuBe p-type ohmic contacts were deposited and annealed at 450° C. for 180 seconds and at 520° C. for 180 seconds, respectively. A 300 nm thick SiO₂ insulator layer was deposited by plasma-enhanced chemical vapor deposition (PECVD). Above the SiO₂ insulator layer, a Ti/Au topgate covers the entire surface of the 2DEG or 2DHG (overlapping the ohmic contacts). Unlike conventional modulation-doped GaAs/AlGaAs heterostructures, it is this topgate that determines the shape of the 2DEG/2DHG, not the etched mesa. Near the p-n junction, the topgate is composed of a single 5 nm thin semi-transparent Ti layer (˜70% transmission) in samples A-D and composed of a single 30 nm thin semi-transparent indium-tin-oxide (ITO) layer (˜85% transmission) for sample E. The topgate gap is the distance between the left topgate (V_{tgL}) and right topgate (V_{tgR}) in FIGS. 3(a) and 3(b), and is also the distance between the p-type and n-type regions. The topgate gap varies from 200 nm to 2,000 nm in samples A-E (see Table 1). An optical photograph of a completed dopant-free p-n junction is shown in FIG. 3(b). Note the presence of n-type and p-type ohmic contacts on both sides of the p-n junction, allowing a two-dimensional electron gas (2DEG) or a two-dimensional hole gas (2DHG) to form. The device can thus be operated in the PN, NP, NN, or PP modes. Electroluminescence occurs only in the PN or NP modes.

Concerning electroluminescence and photoluminescence, all spectra were acquired with a spectrometer grating with a groove density of 1,800 lines/mm, except for the inset of FIG. 3(e) (150 lines/mm). Devices were cooled down either to T=3 K in an Oxford Instruments OptistatDry BLV closed-cycle cryostat or to T=1.6 K in an Attocube AttoDRY2100 closed-cycle cryostat, both with in-house customized DC and RF electrical feedthroughs. Unless specified otherwise, cw photoluminescence was generated from photoexcitation with a HeNe laser (632.8 nm) at 1 mW optical output power. Pulsed photoexcitation for time-resolved photoluminescence was provided by a Ti: sapphire laser operating at 800 nm.

Four observations support the scenario of localized parasitic charging of lateral p-n junctions:
(i) decay of EL intensity with time [see FIG. 3(e)];
(ii) faster quenching of EL with larger forward bias currents [see FIG. 3(e)];
(iii) brighter EL when operating a device in the Set-Reset mode [see FIG. 4(a)]; and
(iv) the “reset” requiring the alternating presence of both 2DEG and 2DHG in the same location to be most effective.

Regarding observations (i)-(iii). Without current flowing across the p-n junction, the 2DEG and 2DHG are otherwise stable: their carrier density does not change with time, and no evidence of undesirable charging is observed. Devices are also stable if a large current flows between ohmic contacts on the same side of the p-n junction, with no current flowing across the p-n junction. These suggest that the charging mechanism making devices unstable is associated with current flowing across the p-n junction. Indeed, from our own experience and that of others, at very high p-n currents (0.2-0.4 mA), dopant-free p-n junctions can be stable in time. In that case, we speculate that any parasitic charge build-up is cleared away by the high currents. We believe this high-current regime is not applicable to the single photon regime, where currents are expected to be six orders of magnitude smaller. We note that electrons/holes can escape the quantum well confinement in significant numbers at/near the p-n junction when the forward bias Vₚₙ is much larger than the quantum well confinement potential.

Regarding observation (iv). In addition to the four ambipolar p-n junctions reported here, “unipolar” p-n junctions were also fabricated, with only n-type ohmic contacts on one side of the p-n junction and only p-type ohmic contacts on the other side. These were also unstable with time (i.e., decaying brightness), similar to their ambipolar cousins. However, the Set-Reset sequences failed to reset these unipolar devices: only full thermal cycles could reset them. Furthermore, if the Set-Reset sequence is only applied to one side (say, V_{tgR} but not V_{tgL}) of an ambipolar p-n junction, then light emission lasts longer than in DC mode but not as long as when the Set-Reset sequence is applied to both V_{tgR} and V_{tgL}. These two results strongly suggest an efficient “reset” mechanism must involve the presence of alternating 2DEGs and 2DHGs in the same physical location, with its associated reversal of the electric field direction.

A scenario for parasitic local charging in dopant-free lateral p-n junctions can be formulated. During EL emission, driven by the electric fields from Vₚₙ, V_{tgL}, and V_{tgR} present at the p-n junction, electrons (holes) tunnel/escape from their 2DEG (2DHG) quantum well into the surrounding GaAs/AlGaAs material and to the GaAs/SiO₂ interface at the wafer surface. This parasitic charge build-up either enhances non-radiative electron-hole recombination, or counters the forward bias enough to altogether suppress current across the p-n junction. By reversing the directions of all electric fields (except Vₚₙ) in the p-n junction during the “reset” cycle of the Set-Reset sequence, all or most of the trapped electron (hole) charge is dislodged from the static traps and driven to recombine with the newly-formed 2DHG (2DEG) nearby.

Finally, we discuss the applicability of the Set-Reset protocol to dopant-free single-photon sources, such as the one recently demonstrated, driven by surface acoustic waves, or a proposed source realized by placing a dopant-free non-adiabatic single electron pump next to a lateral p-n junction. In the single photon regime, we expect forward bias currents three to four orders of magnitude smaller (160 pA if the single electron pump operates at 1 GHZ) than the EL data presented here, which was acquired in continuous Set-Reset mode. We therefore anticipate parasitic charging to be very slow, and a Set-Reset sequence may only be required infrequently between operating periods.

In conclusion, we have demonstrated electroluminescence up to a temperature of 85 K in ambipolar lateral p-n junctions based on gated dopant-free GaAs/AlGaAs quantum wells. These were operated in the Set-Reset mode, which dissipated parasitic charge accumulation and eliminated the need for a thermal cycle to room temperature to reset unstable devices. The Set-Reset protocol enabled the observation of the narrowest EL linewidths (0.70 meV) achieved to date in lateral p-n junctions, the measurement of a τ el=237 ps exciton mean lifetime using RF pulsed-EL, the RF operation of devices at frequencies of up to 1.6 GHZ, the characterization of the binding and dissociation energies for free excitons and trions as a function of in-plane electric fields ranging from 8 kV/cm to 80 kV/cm, and is a significant step towards realizing viable quantum light sources based on dopant-free lateral p-n junctions.

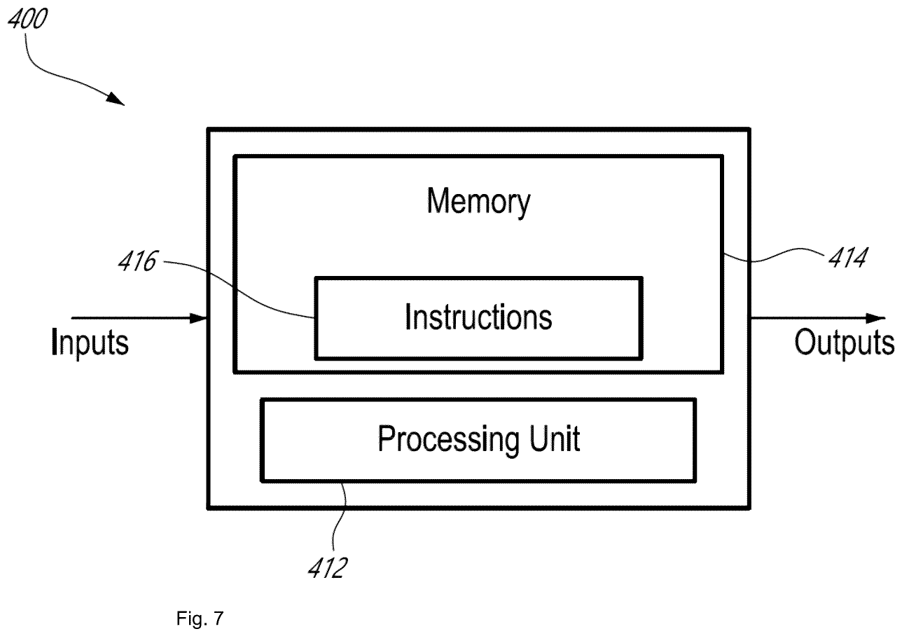

Referring to FIG. 7 it will be understood that the expression “computer” 400 as used herein is not to be interpreted in a limiting manner. It is rather used in a broad sense to generally refer to the combination of some form of one or more processing units 412 and some form of memory system 414 accessible by the processing unit(s). The memory system can be of the non-transitory type. The use of the expression “computer” in its singular form as used herein includes within its scope the combination of a two or more computers working collaboratively to perform a given function. Moreover, the expression “computer” as used herein includes within its scope the use of partial capabilities of a given processing unit.

A processing unit can be embodied in the form of a general-purpose micro-processor or microcontroller, a digital signal processing (DSP) processor, an integrated circuit, a field programmable gate array (FPGA), a reconfigurable processor, and a programmable read-only memory (PROM, to name a few examples.

The memory system can include a suitable combination of any suitable type of computer-readable memory located either internally, externally, and accessible by the processor in a wired or wireless manner, either directly or over a network such as the Internet. A computer-readable memory can be embodied in the form of random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) to name a few examples.

A computer can have one or more input/output (I/O) interface to allow communication with a human user and/or with another computer via an associated input, output, or input/output device such as a keyboard, a mouse, a touchscreen, an antenna, a port, etc. Each I/O interface can enable the computer to communicate and/or exchange data with other components, to access and connect to network resources, to serve applications, and/or perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, Bluetooth, WiMAX), SS7 signaling network, fixed line, local area network, wide area network, to name a few examples.

It will be understood that a computer can perform functions or processes via hardware or a combination of both hardware and software. For example, hardware can include logic gates included as part of a silicon chip of a processor. Software (e.g. application, process) can be in the form of data such as computer-readable instructions stored in a non-transitory computer-readable memory accessible by one or more processing units. With respect to a computer or a processing unit, the expression “configured to” relates to the presence of hardware or a combination of hardware and software which is operable to perform the associated functions. Different elements of a computer, such as processor and/or memory, can be local, or in part or in whole remote and/or distributed and/or virtual.

The methods and systems of the present disclosure may be implemented in a high level procedural or object oriented programming or scripting language, or a combination thereof, to communicate with or assist in the operation of a computer system, for example the controller. Alternatively, the methods and systems described herein may be implemented in assembly or machine language. The language may be a compiled or interpreted language. Program code for implementing the methods and systems described herein may be stored on a storage media or a device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein. Embodiments of the methods and systems described herein may also be considered to be implemented by way of a non-transitory computer-readable storage medium having a computer program stored thereon. The computer program may comprise computer-readable instructions which cause a computer, or more specifically the processing unit 402 of the computing device 400, to operate in a specific and predefined manner to perform the functions described herein, for example those described in the set-reset method.

Computer-executable instructions may be in many forms, including program modules, executed by one or more computers or other devices. Generally, program modules include routines, programs, objects, components, data structures, etc., that perform particular tasks or implement particular abstract data types. Typically the functionality of the program modules may be combined or distributed as desired in various embodiments. The technical solution of embodiments may be in the form of a software product. The software product may be stored in a non-volatile or non-transitory storage medium, which can be a compact disk read-only memory (CD-ROM), a USB flash disk, or a removable hard disk. The software product includes a number of instructions that enable a computer device (personal computer, server, or network device) to execute the methods provided by the embodiments.

The embodiments described herein are implemented by physical computer hardware, including computing devices, servers, receivers, transmitters, processors, memory, displays, and networks. The embodiments described herein provide useful physical machines and particularly configured computer hardware arrangements. The embodiments described herein are directed to electronic machines and methods implemented by electronic machines adapted for processing and transforming electromagnetic signals which represent various types of information. The embodiments described herein pervasively and integrally relate to machines, and their uses; and the embodiments described herein have no meaning or practical applicability outside their use with computer hardware, machines, and various hardware components. Substituting the physical hardware particularly configured to implement various acts for non-physical hardware, using mental steps for example, may substantially affect the way the embodiments work. Such computer hardware limitations are clearly essential elements of the embodiments described herein, and they cannot be omitted or substituted for mental means without having a material effect on the operation and structure of the embodiments described herein. The computer hardware is essential to implement the various embodiments described herein and is not merely used to perform steps expeditiously and in an efficient manner.

As can be understood, the examples described above and illustrated are intended to be exemplary only. For instance, while in the experiment reported above, not only an optional forward bias is applied, it is also maintained constant throughout the process, it will be noted that in some embodiments using a bias, the bias may be varied, even reversed, during the set-reset process. For instance, the bias could be reversed at every reversal of the set-reset process. Moreover, while experiments were conducted on dopant-free GaAs/AlGaAs heterostructure-insulator-gate field effect transistor geometry, it will be understood that the set-reset process may have uses in other embodiments, such as perhaps other undoped gallium arsenide (III-V), silicon-based, e.g. undoped silicon, II-VI geometries, INGAS, undoped Indium Gallium Arsenide, other geometries where quantum well is relatively deep in structure. The scope is indicated by the appended claims.

What is claimed is:

1. A process of operating a p-n junction having a first side and a second side, the first side being a first one of a p side and an n side, the second side being a second one of the p side and the n side, the process comprising:
while maintaining the p-n junction at a temperature below 80° K, in sequence,
1. generating a first one of an electron gas and a hole gas at the first side of the p-n junction, and generating a second one of the electron gas and the hole gas at the second side of the p-n junction;
2. discontinuing both the electron gas and the hole gas;
3. generating the first one of the electron gas and the hole gas at the second side of the p-n junction; and
4. discontinuing the first one of the electron gas and the hole gas at the second side of the p-n junction.

2. The process of claim 1 wherein said first one of the electron gas and the hole gas is the electron gas, the second one of the electron gas and the hole gas is the hole gas.

3. The process of claim 1 wherein said step 3 further includes generating the second one of the electron gas and the hole gas at the first side.

3. The process of claim 1 comprising repeating the steps 1 through 4 more than 10 times, preferably more than 50 times.

4. The process of claim 3 wherein said repeating is performed at a frequency above 1 Hz, above 10 Hz, or above 1 kHz.

5. The process of claim 1 further comprising maintaining a voltage difference between the first side and the second side of the p-n junction, wherein the steps 1 through 4 are performed while maintaining the voltage difference.

6. The process of claim 5 wherein the voltage difference is greater than a band gap of the p-n junction, and said maintaining the voltage difference includes generating light at the p-n junction.

7. The process of claim 1 wherein the p-n junction is a lateral p-n junction based on a dopant-free GaAs/AlGaAs heterostructure-insulator-gate field effect transistor geometry, and wherein said generating an electron gas includes applying a voltage beyond a turn-on threshold at a gate, inducing a two dimensional electron gas underneath the gate and wherein said generating a hole gas includes applying a voltage beyond a turn-on threshold at a gate, inducing a two dimensional hole gas underneath the gate.

8. The process of claim 1 wherein the p-n junction is dopant free.
